(19) United States
(12) Patent Application Publication
(10) Pub. No.: US 2026/0331164 A1
(43) Pub. Date: Oct. 22, 2026

(54) CAPTURE AND SHIFT CIRCUITRY FOR HBM DEVICES

(71) Applicant: Micron Technology, Inc., Boise, ID (US)

(72) Inventor: Abishek Namachivayam, Boise, ID (US)

(21) Appl. No.: 19/554,411

(22) Filed: Mar. 2, 2026

Related U.S. Application Data
(60) Provisional application No. 63/792,195, filed on Apr. 21, 2025.

(51) Int. Cl. G11C 11/4093; G11C 11/4076; G11C 19/28

(52) U.S. Cl. CPC G11C 11/4093; G11C 11/4076; G11C 19/287

(57) ABSTRACT

Systems and methods are provided for using a memory system that includes one or more memory dies and multiple data (DQ) pads configured to send and receive bit. The system also includes a PHY communicatively coupled to the one or more memory dies and configured to communicate using the multiple DQ pads. The PHY includes a first path having a shift chain of registers configured to serialize a first subset of bits of the DQ pads into an output. The PHY also includes a second path configured to bypass the shift chain for a second subset of bits of the DQ pads when serialized with the first subset of bits into the output.

### CROSS-REFERENCE TO RELATED APPLICATION

This application claims priority to U.S. Provisional Application No. 63/792,195, filed Apr. 21, 2025, which is incorporated by reference herein in its entirety.

### BACKGROUND OF THE INVENTION

### Field of the Invention

The present disclosure relates generally to the field of semiconductor memory devices. More specifically, embodiments of the present disclosure relate to interface circuitry of a memory device.

### Description of the Related Art

A memory device may include a number of dies, and each die may include a number of memory arrays and peripheral circuitry thereon, such as die logic or a die processor. The memory device may be a high bandwidth memory (HBM) device, which may include an interface die (or base die) and one or more core dies stacked on the interface die. The interface die includes interface circuitry to communicate with a host device through a communication interface. The memory device may receive commands or operations from the host device through the communication interface, such as read or write operations to transfer data (e.g., user data and associated integrity data, such as error data or address data, etc.) between the memory device and the host device, erase operations to erase data from the memory device, or drive management operations (e.g., data migration, garbage collection, block retirement), etc. The communication interface may include a physical interface (PHY) that includes capture and shift circuitry to capture data. However, the PHY may have a specified timing that may be difficult to capture data properly within the specified timing.

### BRIEF DESCRIPTION OF THE DRAWINGS

Various aspects of this disclosure may be better understood upon reading the following detailed description and upon reference to the drawings in which:

FIG. 1 is a cross-section of an embodiment of a system including a memory device having a PHY, according to an embodiment of the present disclosure;

FIG. 2 is a simplified block diagram showing a perspective view of a portion of the memory device of FIG. 1, according to an embodiment of the present disclosure;

FIG. 3 is a simplified block diagram illustrating certain features of the memory device of FIG. 1, according to an embodiment of the present disclosure;

FIG. 4 is a timing diagram in a capture of data in the PHY of FIG. 1, according to an embodiment of the present disclosure;

FIG. 5A is a timing diagram an EXTEST_RX instruction in the PHY of FIG. 1, according to an embodiment of the present disclosure;

FIG. 5B is a timing diagram an EXTEST_TX instruction in the PHY of FIG. 1, according to an embodiment of the present disclosure;

FIG. 6 is a circuit diagram of a portion of the PHY of FIG. 1, according to an embodiment of the present disclosure;

FIG. 7 is a circuit diagram of a portion of the PHY of FIG. 1 with a faster path for at least some bits (e.g., Bit 0), according to an embodiment of the present disclosure; and

FIG. 8 is a timing diagram showing usage of the portion of FIG. 7, according to an embodiment of the present disclosure.

### DETAILED DESCRIPTION OF SPECIFIC EMBODIMENTS

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers’ specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

As mentioned previously, a memory device may be a high bandwidth memory (HBM) device, which may include an interface die (or base die) and one or more dies stacked on the interface die to form a vertically stacked three-dimensional (3D) HBM cube. The interface die includes a physical interface (PHY) to communicate with a host device through a communication interface. In some embodiments, the host device may use a predefined PHY that has a specification to communicate with the memory device.

As noted below, timing may be relatively tight for various instructions to be implemented in an HBM (e.g., EXTEST_TX) that may make staying within specification difficult especially for a first one or more bits (e.g., Bit 0). Thus, as discussed below, the PHY may use a faster path that bypasses at least some circuitry that other bits (e.g., Bits 1-15) pass through during the serialization of bits from parallel DQ pads. For instance, Bit 0 may bypass the shift register chain that uses delayed clocks entirely. Instead, Bit 0 may be transmitted directly from a respective input buffer without being transmitted to the shift register chain like the other bits experience. Thus, some bits (e.g., Bit 0) are serialized via a different path than subsequent bits (e.g., Bits 1-15, etc.). As discussed below, this use of a faster path for the early bit(s) (e.g., earliest Bit 0) in a serialized output may cause the early bit(s) to be captured more quickly thereby reducing the likelihood of capturing invalid data when trying to capture the early bit(s). As discussed below, the early bit(s) may also bypass instruction decode multiplexing that is instead performed closer to the output. As discussed below, as the bits of a serialized output are transmitted through different paths, a control mechanism (e.g., a control latch) may be used to control which path is selected. When an applicable serialized output is to be captured (e.g., pulse of a CaptureWR signal), the early bit(s)’s path may be selected, but once a shift is to occur of bits through the second path (e.g., shift in the shift chain), the other path is to be selected.

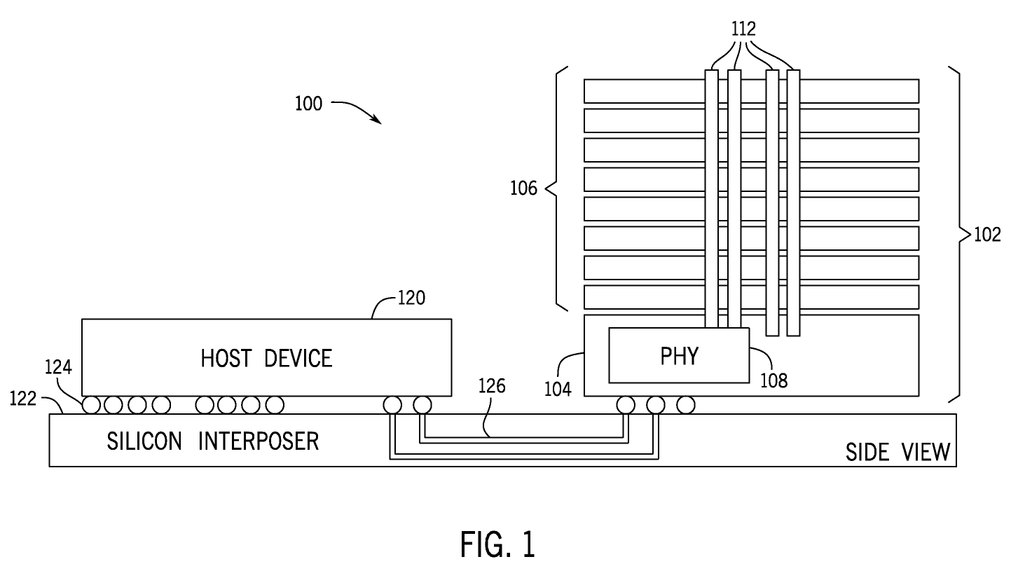

Turning now to the figures, FIG. 1 is a cross-section of a system 100 including a memory device 102 and a host device 120 according to an embodiment of the present disclosure. Although one memory device is shown for the depicted example, a number of memory devices greater than one may be used. A memory device 102, as shown in the embodiment of FIG. 1, may be a high bandwidth memory (HBM) device (e.g., HBM cube), which includes an interface die (or base die) 104 and one or more memory dies 106 stacked on the interface die 104. The interface die 104 may include one or more physical interfaces (PHY) 108. The memory device 102 may include one or more Through-Wafer Interconnects (TWIs) 112 to couple the interface die 104 and the dies 106. If the integrated circuits are silicon-based, these may also be known as Through-Silicon Vias (TSVs).

The system 100 of the memory device 102 may include a host device 120. The host device 120 and the memory device 102 may be coupled to an interposer 122 (e.g., a silicon interposer) via a number of micro-bumps 124. The interposer 122 may include channels 126 that may be used to communicatively couple the host device 120 with the memory device 102 via corresponding micro-bumps 124. Although only two channels 126 are shown in FIG. 1, greater or fewer numbers of channels 126 may be used.

In an embodiment, the host device 120 may be coupled to the PHY 108 of the interface die 104 via a predefined communication interface, as illustrated in FIG. 1. The memory device 102 may receive commands or operations from the host device 120 through the channels 126, such as read or write operations to transfer data (e.g., user data and associated integrity data, such as error data or address data, etc.) between the memory device 102 and the host device 120, erase operations to erase data from the memory device 102, or drive management operations (e.g., data migration, garbage collection, block retirement), etc. In the embodiment illustrated in FIG. 1, the PHY 108 of the interface die 104 may be used for testing the memory device 102.

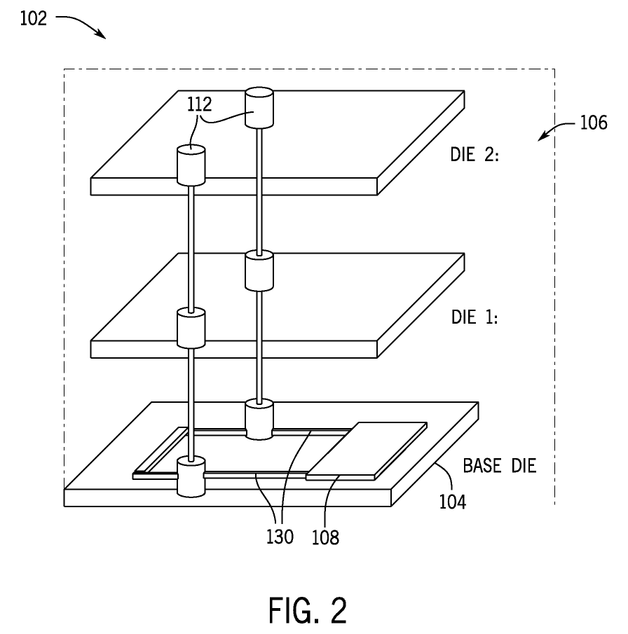

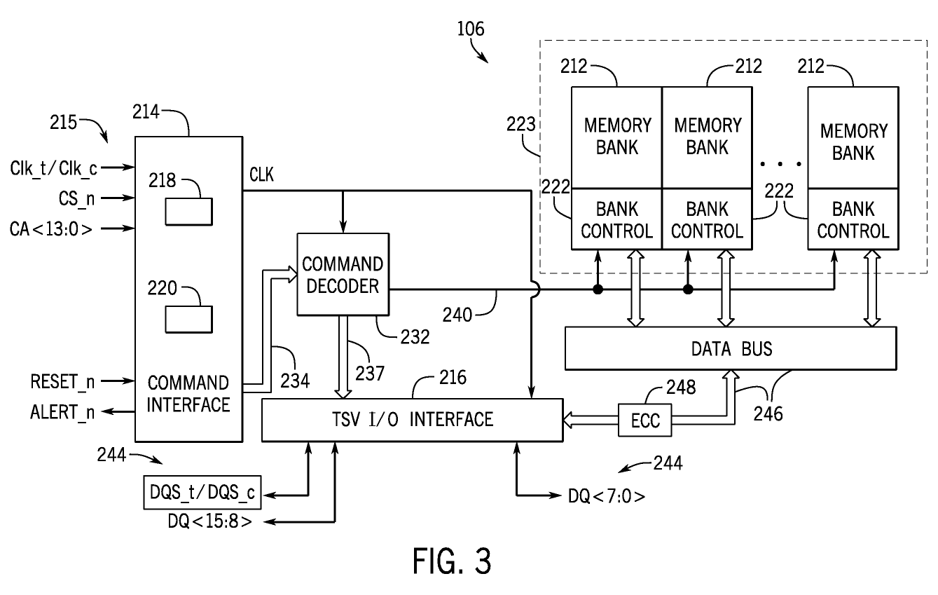

FIG. 2 is a simplified block diagram showing a perspective view of a portion of the memory device 102. As illustrated in FIG. 2, the PHY 108 of the interface die 104 may be communicatively coupled to the TWIs 112 via channels 130. Although only two channels 130 are shown in FIG. 2, greater or fewer numbers of channels 130 may be used. In some embodiments, commands or operations from the host device 120 may be transmitted to the memory device 102 via the PHY 108, such as read or write operations to transfer data (e.g., user data and associated integrity data, such as error data or address data, etc.), erase operations to erase data, or drive management operations (e.g., data migration, garbage collection, block retirement), etc. The commands or operations received by the PHY 108 may be transmitted to the dies 106 via the channels 130 and the TWIs 112. Each of the dies 106 (e.g., die 1, die 2…) may include interface circuitry to communicate with the interface die 104, as illustrated in FIG. 3. Corresponding data may be transmitted between the dies 106 and the PHY 108 via the TWIs 112 and the channels 130, and the corresponding data may be transmitted between the host device 120 and the memory device 102 via the PHY 108.

As previously noted, the PHY 108 may include more than one physical interface, such as a 2.5D physical interface and/or a 3D physical interface that are both communicatively coupled to the TWIs 112 to couple the interface die 104 and the dies 106 (e.g., die 1, die 2…) of the memory device 102. For instance, the PHY 108 may include the physical interfaces disclosed in U.S. Patent Application No. 18/951,103, entitled “HBM BASE DIE WITH 2.5D and 3D PHY INTERFACE,” filed on Nov. 18, 2024, that is incorporated herein in its entirety for all purposes.

FIG. 3 is a simplified block diagram illustrating certain features of the dies 106 of the memory device 102 in an embodiment. Specifically, the block diagram of FIG. 3 is a functional block diagram illustrating certain functionality of the dies 106. In accordance with one embodiment, the dies 106 may be dynamic random access memory (DRAM) dies.

Each of the dies 106 may include a number of memory banks 212. The memory banks 212 may be DRAM memory banks, for instance. Each of the dies 106 may include a command interface 214 and a TWI interface, such as a TSV input/output (I/O) interface 216, to exchange (e.g., receive and transmit) signals with the interface die 104 (e.g., via the TWIs 112). The command interface 214 may receive a number of signals (e.g., signals 215) from the interface die 104. The interface die 104 may provide various signals 215 to the dies 106 to facilitate the transmission and receipt of data to be written to or read from the dies 106.

As will be appreciated, the command interface 214 may include a number of circuits, such as a clock input circuit 218 and a command/address input circuit 220, for instance, to ensure proper handling of the signals 215. The command interface 214 may receive one or more clock signals from the interface die 104. Generally, HBM memory utilizes a differential pair of system clock signals, referred to herein as the true clock signal (Clk_t) and the complementary clock signal (Clk_c). The positive clock edge for HBM refers to the point where the rising true clock signal Clk_t crosses the falling complementary clock signal Clk_c, while the negative clock edge indicates that transition of the falling true clock signal Clk_t and the rising of the complementary clock signal Clk_c. Commands (e.g., read command, write command, etc.) are typically entered on the positive edges of the clock signal and data is transmitted or received on both the positive and negative clock edges.

The clock input circuit 218 receives the true clock signal (Clk_t) and the complementary clock signal (Clk_c) and generates an internal clock signal CLK, which is supplied to the TSV I/O interface 216, for instance, and is used as a timing signal for determining an output timing of read data. The internal clock signal CLK may also be provided to various other components within the dies 106 and may be used to generate various additional internal clock signals. For instance, the internal clock signal CLK may be provided to a command decoder 232. The command decoder 232 may receive command signals from a command bus 234 and may decode the command signals to provide various internal commands. The command decoder 232 may also provide command signals to the TSV I/O interface 216 over a bus 237 to facilitate receiving and transmitting I/O signals. The clock signal CLK may also be used to clock data through the TSV I/O interface 216, for instance.

Further, the command decoder 232 may decode commands received from the command bus 234, such as read commands, write commands, mode-register set commands, activate commands, etc., and provide access to a particular memory bank 212 corresponding to the command, via the bus path 240. As will be appreciated, the dies 106 may include various other decoders, such as row decoders and column decoders, to facilitate access to the memory banks 212. In one embodiment, each memory bank 212 includes a bank control block 222 which provides the necessary decoding (e.g., row decoder and column decoder), as well as other features, such as timing control and data control, to facilitate the execution of commands to and from the memory banks 212. A group of the memory banks 212 may be included in a memory channel 223, and the dies 106 may include one or more channels.

The dies 106 execute operations, such as read commands and write commands, based on the command/address signals received from the interface die 104. In one embodiment, the command/address bus may be a 14-bit bus to accommodate the command/address signals (CA<13:0>). The command/address signals are clocked to the command interface 214 using the clock signals (Clk_t and Clk_c). The command/address input circuit 220 in the command interface 214 may receive and transmit the commands to provide access to the memory banks 212, through the command decoder 232, for instance. In addition, the command interface 214 may receive a chip select signal (CS_n). The chip select signal CS_n enables the dies 106 to process commands on the incoming command/address signals CA<13:0> for the memory chip selected by the chip select signal CS_n. Accordingly, access to specific banks 212 within the dies 106 is facilitated by the information encoded on the chip select signal CS_n and the command/address signals CA<13:0>.

In addition, the command interface 214 may receive a number of other command signals. For instance, a reset command (RESET_n) may be used to reset the command interface 214, status registers, state machines and the like, during power-up for instance. The command interface 214 may also be used to provide an alert signal (ALERT_n) to the system processor or controller for certain errors that may be detected. For instance, an alert signal (ALERT_n) may be transmitted from the dies 106 if a cyclic redundancy check (CRC) error is detected. Other alert signals may also be generated. Further, the bus and pin for transmitting the alert signal (ALERT_n) from the dies 106 may be used as an input pin during certain operations, such as the connectivity test mode executed using the TEN signal, as described above.

Data may be sent to and from the dies 106, utilizing the command and clocking signals discussed above, by transmitting and receiving data signals 244 through the TSV I/O interface 216. More specifically, the data may be sent to or retrieved from the memory banks 212 over the data bus 246, which includes a plurality of bi-directional data buses. The Data I/O signals, generally referred to as DQ signals, are generally transmitted and received in one or more bi-directional data busses. In certain embodiments, an error correction code (ECC) system 248 may be used to detect, and in some cases, resolve, data errors that may arise. For example, incorrect bits may be retrieved via a memory read command and the ECC system 248 may detect, and in some cases correct, the read data. The ECC system 248 may additionally raise a flag if, for example, correction may not be possible.

To allow for higher data rates within the dies 106, certain memory devices, such as HBM memory devices, may utilize data strobe signals, generally referred to as DQS signals. The DQS signals are driven by the external processor or controller sending the data (e.g., for a write command) or by the dies 106 (e.g., for a read command). For read commands, the DQS signals are effectively additional data output (DQ) signals with a predetermined pattern. For write commands, the DQS signals are used as clock signals to capture the corresponding input data. As with the clock signals (Clk_t and Clk_c), the data strobe (DQS) signals may be provided as a differential pair of data strobe signals (DQS_t and DQS_c) to provide differential pair signaling during reads and writes.

As will be appreciated, various other components such as power supply circuits (for receiving external VDD and VSS signals), mode registers (to define various modes of programmable operations and configurations), read/write amplifiers (to amplify signals during read/write operations), temperature sensors (for sensing temperatures of the dies 106), etc., may also be incorporated into the dies 106. Accordingly, it should be understood that the block diagram of FIG. 3 is only provided to highlight certain functional features of the dies 106 to aid in the subsequent detailed description.

As discussed above, data may be written to and read from the dies 106, for example, by the host device 120 whereby the dies 106 operate as volatile memory, such as HBM memory. The host device 120 may, in some embodiments, also include separate non-volatile memory, such as read-only memory (ROM), PC-RAM, silicon-oxide-nitride-oxide-silicon (SONOS) memory, metal-oxide-nitride-oxide-silicon (MONOS) memory, polysilicon floating gate based memory, and/or other types of flash memory of various architectures (e.g., NAND memory, NOR memory, etc.) as well as other types of memory devices (e.g., storage), such as solid state drives (SSD’s), MultimediaMediaCards (MMC’s), SecureDigital (SD) cards, CompactFlash (CF) cards, or any other suitable device. Further, it should be appreciated that the host device 120 may include one or more external interfaces, such as Universal Serial Bus (USB), Peripheral Component Interconnect (PCI), PCI Express (PCI-E), Small Computer System Interface (SCSI), IEEE 1394 (Firewire), or any other suitable interface as well as one or more input devices to allow a user to input data into the host device 120, for example, buttons, switching elements, a keyboard, a light pen, a stylus, a mouse, and/or a voice recognition system, for instance. The host device 120 may optionally also include an output device, such as a display coupled to the processor and a network interface device, such as a Network Interface Card (NIC), for interfacing with a network, such as the Internet. As will be appreciated, the host device 120 may include many other components, depending on the application of the host device 120.

The memory device 102 may have a specification for the PHY 108 and/or general operation. For instance, the memory device 102 may use the JEDEC HBM 2.0, 3.0, 4.0, or other similar standards. As part of such standards, the memory device 102 may be constrained to other specifications, such as IEEE 1500 testability standard. As such, the PHY 108 may include interface circuitry for implementing such standards. Indeed, such standards may utilize serial ports and/or a wrapper clock (WRCK). The WRCK may be different than at least some other parts of the memory device 102. For example, the WRCK may be slower than a clock (e.g., Ck_t) used by dies 106 in their memory banks 212.

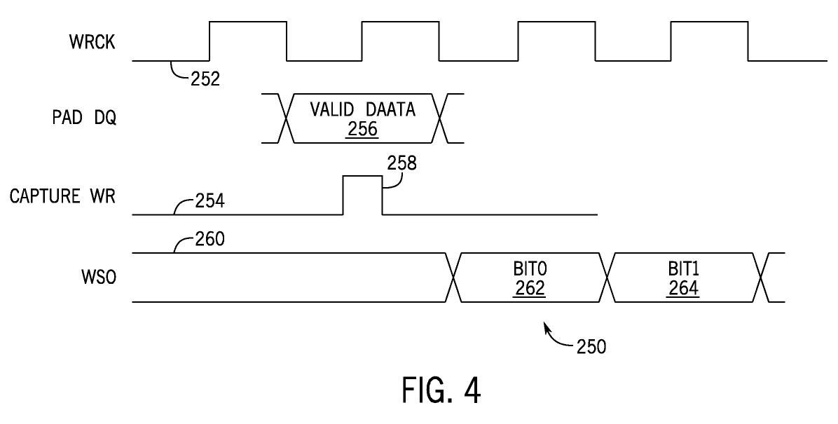

FIG. 4 is a timing diagram 250 that may be used in the PHY 108. As previously noted, the PHY 108 may utilize a WRCK, represented by line 252, that is the wrapper clock for the serial port (e.g., IEEE Port 1500). The timing diagram 250 also shows that the memory device 102 may capture data from a pad DQ (e.g., DQ0 to DQ15). The timing diagram 250 also shows that a CaptureWR is an IEEE wrapper serial port capture signal. CaptureWR, represented by line 254, is a capture enable signal that enables captures of input data, such as valid data 256, in a register (e.g., wrapper data register (WDR)) when a pulse 258 occurs on the CaptureWR when the memory device 102 is in a corresponding mode (e.g., EXTEST_RX is enabled). In other modes, other signals (e.g., ShiftWR) may be used to enable shifting in a respective register. For example, a register may shift values (e.g., from WDR) in other modes (e.g., EXTEST_TX). The captured bits may be output from a wrapper serial output (WSO), represented by line 260. The WSO serially outputs bits (e.g., bit0 262, bit1 264, etc.).

As may be appreciated, the standards may support various board testing modes. The EXTEST_RX and EXTEST_TX are instructions to confirm data connectivity with data sent to/received from the memory controller of the memory device 102. EXTEST_RX and EXTEST_TX are used for I/O connectivity testing similar to board level boundary scans. In EXTEST_RX, the I/O samples the logic value at the PAD DQ (e.g., valid data 256) and captures it into the data register(s) (WDR). Although the following discusses IEEE 1500 EXTEST_RX and EXTEST_TX, any other modes may be deployed in the memory device 102. In EXTEST_TX, the I/O drives the logic value into the data register at the microbump interface (e.g., the PAD DQ). EXTEST_RX and EXTEST_TX are forms of I/O connectivity testing similar to board level boundary scans.

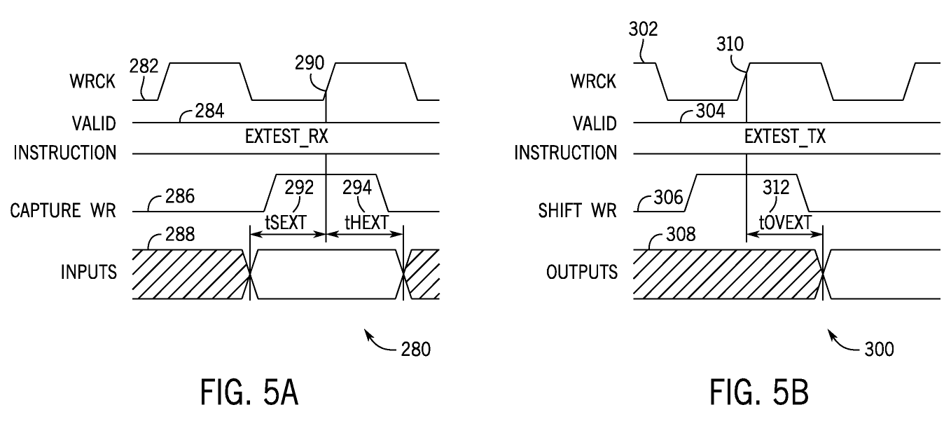

The use of such modes may have prescribed timing that may be relatively difficult to meet. For instance, FIG. 5A is a timing diagram 280 of an EXTEST_RX instruction. As illustrated, WRCK, represented by line 282, is used for timing in the PHY 108 where a valid instruction, represented by line 284, indicates an EXTEST_RX instruction. Since the instruction is an EXTEST_RX instruction, a pulse on the CaptureWR, represented by line 286 is used to indicate that inputs, represented by line 288, are to be captured into the WDR(s).

The data from the inputs may be sampled from the microbumps/pad on a rising edge 290 of WRCK while CaptureWR is asserted during EXTEST_RX. The memory device 102 may have a defined timing (e.g., as part of HBM/IEEE 1500 specification) of tSEXT 292 that indicates an input setup time before the rising edge 290. The memory device 102 may also have a defined timing of tHEXT 294 that indicates a hold time to a falling edge of WRCK.

FIG. 5B is a timing diagram 300 of an EXTEST_TX instruction. As illustrated, WRCK, represented by line 302, is used for timing in the PHY 108 where a valid instruction, represented by line 304, indicates an EXTEST_TX instruction. Since the instruction is an EXTEST_TX instruction, a pulse on the ShiftWR, represented by line 306, is used to indicate that data is to be shifted to outputs (e.g., WSO), represented by line 308.

The data may be shifted to the outputs on the microbumps/pad on a rising edge 310 of WRCK while ShiftWR is asserted during EXTEST_TX. The memory device 102 may have a defined timing (e.g., as part of HBM/IEEE 1500 specification) of tOVEXT 312 that indicates an output valid time that the outputs are to be valid after the rising edge 310.

The bit0 (e.g., Bit0 262) may have one of the tightest timings in the HBM specification. For example, the microbump pin data may be sampled by a rising edge of WRCK and sent out to WSO within an output valid time from a falling edge of the WRCK (e.g., 7 ns). This turnaround may be difficult to meet as these signals may travel to multiple different locations in the memory device 102 and/or the dies 106.

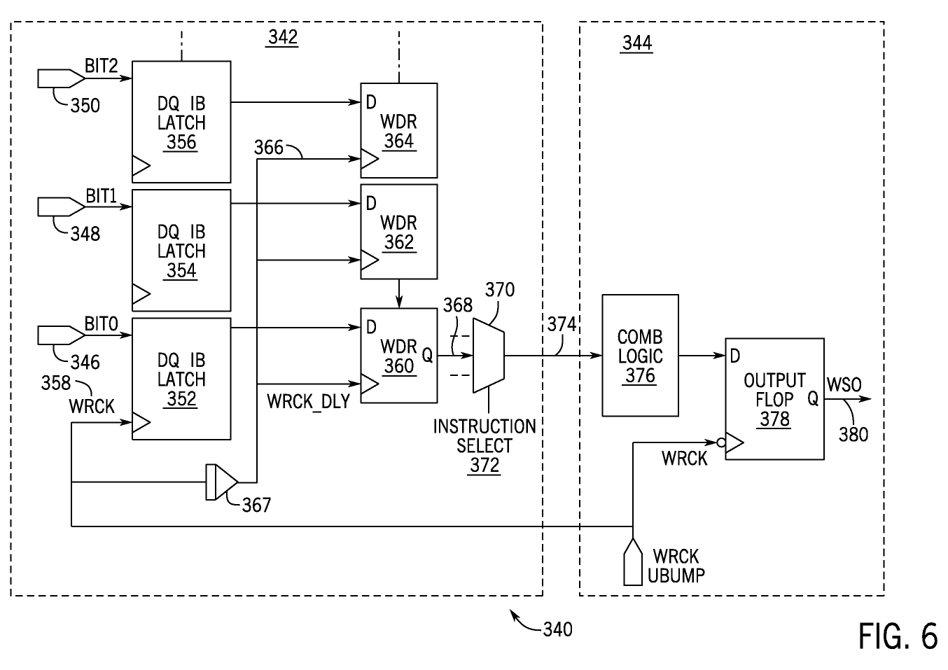

FIG. 6 is a circuit diagram of an interface 340 that may be part of the PHY 108. The interface 340 includes physical channel circuitry 342 (e.g., BPhyCh) and mid circuitry 344 (e.g., BPMid). The physical channel circuitry 342 is used to capture bits from DQ pads. The DQ pads may each be assigned to capture a respective bit of data. For instance, Bit0 pad 346 may capture bit 0 of DQ bits, Bit1 pad 348 may capture bit 1 of the DQ bits, Bit2 pad 350 may capture bit 2 of the DQ bits, and so on. Although 3 bits are used for illustration, any suitable number of bits may be captured in respective DQ pads and transmitted as discussed below.

The values from each DQ bit are captured in respective input buffer latches 352, 354, and 356. The input buffer latches 352, 354, and 356 capture respective values from respective DQ pads. The input buffer latches 352, 354, and 356 each capture their respective bits using the wrapper clock (WRCK) 358 that may be received at the interface 340 (e.g., from the host device 120 and/or based on a clock received from the host device 120). The input buffer latches 352, 354, and 356 may capture the DQ bits in parallel from the respective DQ pads.

The bits captured into the input buffer latches 352, 354, and 356 in parallel from the DQ pads are then serialized in respective wrapper data registers (WDRs) 360, 362, and 364 and so on. The WDRs (e.g., WDRs 360, 362, and 364) capture data from the respective input buffer latches (e.g., respective input buffer latches 352, 354, and 356). The WDRs 360, 362, and 364 capture the data from the input buffer latches 352, 354, and 356 using a delayed WRCK (WRCK_DLY) 366 that is generated from the WRCK 358 using a delay 367. The capture in the WDRs 360, 362, and 364 is based on the WRCK 358 as is the input buffer latches 352, 354, and 356. However, the capture in the WDRs 360, 362, and 364 is delayed to keep from violating setup timing of the input buffer latches 352, 354, and 356 and ensuring that the output of the input buffer latches 352, 354, and 356 are valid before latching the inputs of the WDRs 360, 362, and 364.

Each pulse of the WRCK_DLY 366 results in shift of a bit out the WDR 360 as an output 368 that serializes data from the DQ PADs. The same pulse of WRCK_DLY 366 that causes the WDR 360 to output a bit also causes the WDR 362 to shift out a bit of the parallel bits into the WDR 360 as the next bit to be output from the WDR 360. Similarly, the bit stored in the WDR 364 is shifted into the WDR 362 where it is held until the next pulse of the WRCK_DLY 366 where it is to be shifted to WDR 360 and then later output from the WDR 360 as output 368 on a later pulse of the WRCK_DLY 366. This continues for each bit in a stream (e.g., DQ bits 0-15) capturable in parallel at the DQ pads. Thus, the WDRs act as a shift chain that takes these values and serializes them into the output 368.

The delay of capture in the WDRs 360, 362, and 364 slows down the output 368 further. The output 368 is transmitted to selection circuitry 370 (e.g., a multiplexer) that selects which selected output 374 is to be selected and outputted from the selection circuitry. The selection circuitry 370 selects the output 368 based on an instruction mode indicated by an instruction select 372. For instance, the instruction select 372 may select the output 368 when a corresponding mode (e.g., EXTEST_RX) is active.

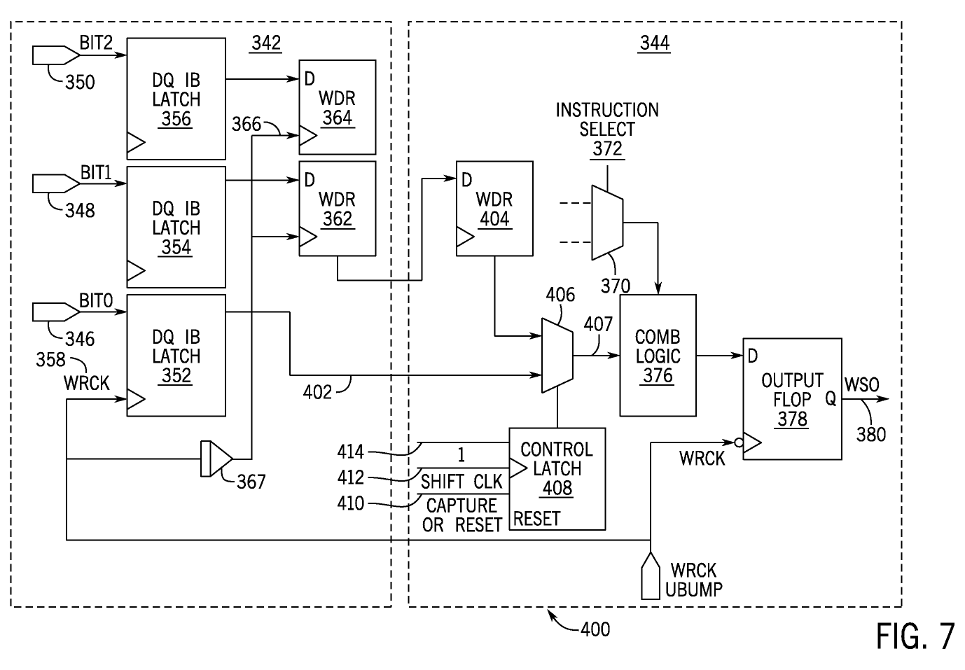

The output 374 is output from the selection circuitry 370 and input to combination logic 376 that may combine the output 374 with other values. In some embodiments, the selection circuitry 370 may be relatively far from the combination logic 376 thereby exacerbating the delay occurring due to the selection circuitry 370. The output of the combination logic 376 is transmitted to an output flip flop 378 that outputs a wrapper serial output (WSO) 380. The instruction selection (e.g., multiplexing) in the instruction circuitry 370 may add additional path delay that may be problematic for time constraints (e.g., tSEXT) for at least some bits (e.g., Bit0). To address potential timing concerns, the PHY 108 may include a different interface, such as interface 400 of FIG. 7, that at least partially alleviates the timing concerns for at least some bits (e.g., Bit 0) during tight timing sequences, such as tSEXT for EXTEST_RX.

As illustrated, the interface 400 functions similarly to the interface 340 to serialize data from the DQ pads to the WSO 380. However, the WDR 360 and the selection circuitry 370 are no longer in the path of Bit0. Instead, data from the Bit0 pad 346 is held in the input buffer latch 352 rather than in WDR 360. As such, the data from the Bit0 pad 346 is output from the input buffer latch 352 directly to the mid circuitry 344 without latching the data in the WDR 360. The mid circuitry 344, as shown in FIG. 7, contains the combination logic 376 and the WSO 380.

In other words, as illustrated in FIG. 7, Bit0 has a separate path 402 that may be faster than paths used for other bits (e.g., Bits 1-15, etc.) through the WDR chain including WDRs 362 and 364. For instance, at least one bit (e.g., Bit0) may bypass the WDR shift chain entirely with a remainder of the bits passing through the WDR shift chain. Instead, some bits (e.g., Bit 0 and/or one or more other bits) traverse through the separate path 402 while remaining bits (e.g., Bits 1-15) traverse through another path that includes the WDR shift chain (and WDR 404). Thus, although the WDR 360 is omitted from the path of the Bit0, a new WDR 404 may be included to ensure shifting of the bits in the WDR shift chain ends up on the proper clock cycles. However, this WDR 404, unlike the WDR 360, may be moved to the mid circuitry 344.

Since the bits from the pads may be transmitted through different paths, selection circuitry 406 may be used to select which path to use for transmitting to the combination logic 376 as selected data 407. This selection circuitry 406 may be used to switch between the faster path (e.g., path 402) for a first set of bit(s) (e.g., Bit 0) and a slower path via the WDR shift chain for other bit(s) (e.g., Bits 1-15). As may be appreciated, this selection circuitry 406 may be processed faster than the selection circuitry 370 as the selection circuitry 406 may have considerably fewer inputs and/or not reliant on waiting for instruction decoding.

As shown in FIG. 7, the selection circuitry 370 may be moved to the mid circuitry 344 and used for instructions/modes where the faster path 402 may be avoided. Instead, in using the selection circuitry 406, a control latch 408 may be used to control which path is selected. As shown in the control latch 408, when a capture (e.g., CaptureWR) or reset is received, the control latch 408 may be reset to the faster path 402 for Bit 0. After a pulse of the shift clock 412, the control latch 408 latches in a data value (e.g., 1) 414 that indicates that the path with the WDR shift chain is to be selected via the selection circuitry 406. In other words, when a new capture is to occur, the control latch 408 controls the selection circuitry 406 to select the faster path 402 for a shift clock pulse switches paths.

As such, the interface 400 is different than the interface 340 as the interface 400 includes a faster path for Bit 0 (and/or other beginning bits) in the serialized WSO 380 and the WDR shift chain for later bits of the serialized WSO 380. The remaining portions of the interface 400 functions similar to how the interface 340 functions as discussed above in relation to FIG. 6.

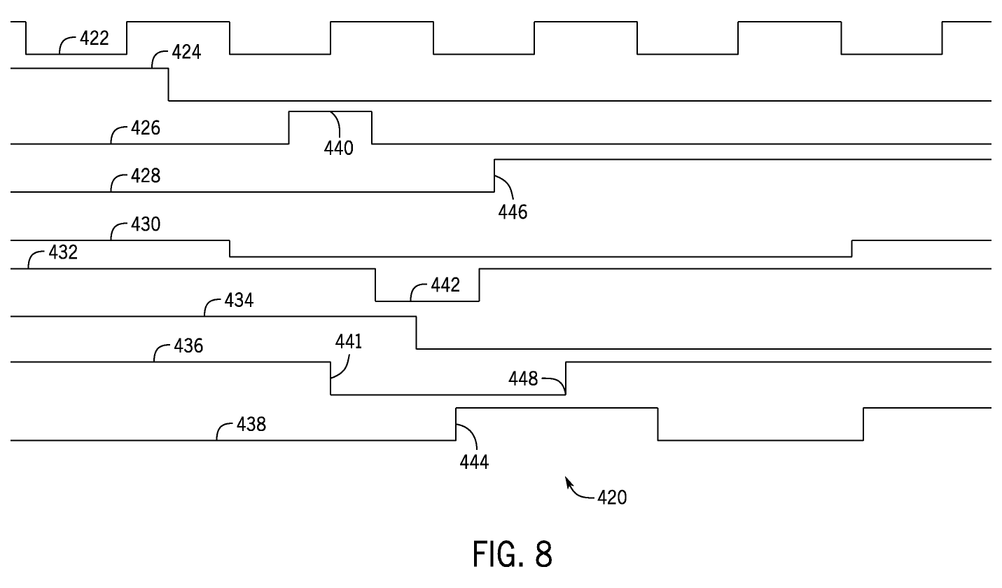

FIG. 8 is a timing diagram 420 of signals in the interface 400. The timing diagram 420 includes a line 422 that represents the WRCK. The timing diagram 420 also includes a line 424 that corresponds to a SelectWIR signal that determines the type of write operation (e.g., instruction or data) being performed. The timing diagram 420 further includes a line 426 that corresponds to the CaptureWR previously discussed. Furthermore, the timing diagram 420 also includes a line 428 that corresponds to the ShiftWR previously discussed. Moreover, the timing diagram 420 includes a line 430 that corresponds to a pad DQ of a bit (e.g., Bit 0) of DQ. The timing diagram 420 further includes a line 432 that corresponds to the signal through the faster path 402 for Bit 0. The line 434 may correspond to the selected data 407. The line 436 may correspond to the control output from the control latch 408. The line 438 may correspond to the WSO 380 (or its complementary WSO_B).

A pulse 440 on the line 426 corresponding to a pulse of the CaptureWR causes the control latch 408 to reset and to transition 441 the line 436 to cause the faster path 402 to be selected. The faster transit of Bit 0 via the faster path 402 is shown by the change 442. Bit 0 is then output 444 on the WSO (WSO_B) reflected by line 438 based on the falling edge of WRCK reflected by line 422. A change 446 in the ShiftWR signal reflected by line 428 causes the control latch 408 to latch in its input value (e.g., 1) that causes the selection circuitry 406 to select the WDR shift chain path from the WDR 404 instead of the faster path 402 used for Bit 0. This causes a change 448 in the control output reflected by line 438 that switches paths to the WDR shift chain until it is again reset on the next pulse of CaptureWR and/or a specific reset signal.

While the present disclosure may be susceptible to various modifications and alternative forms, specific embodiments have been shown by way of example in the drawings and have been described in detail herein. However, it should be understood that the present disclosure is not intended to be limited to the particular forms disclosed. Rather, the present disclosure is intended to cover all modifications, equivalents, and alternatives falling within the spirit and scope of the present disclosure as defined by the following appended claims.

The techniques presented and claimed herein are referenced and applied to material objects and concrete examples of a practical nature that demonstrably improve the present technical field and, as such, are not abstract, intangible, or purely theoretical. Further, if any claims appended to the end of this specification contain one or more elements designated as “means for [perform]ing [a function]…” or “step for [perform]ing [a function]…”, it is intended that such elements are to be interpreted under 35 U.S.C. 112(f). However, for any claims containing elements designated in any other manner, it is intended that such elements are not to be interpreted under 35 U.S.C. 112(f).

What is claimed is:

1. A system, comprising:
one or more memory dies;
a plurality of data (DQ) pads configured to send and receive bits of data; and
a PHY communicatively coupled to the one or more memory dies and configured to communicate using the plurality of DQ pads, wherein the PHY comprises:
a first path comprising a shift chain of registers configured to serialize a first subset of bits of the plurality of DQ pads into an output; and
a second path configured to bypass the shift chain for a second subset of bits of the plurality of DQ pads when serialized with the first subset of bits into the output.

2. The system of claim 1, wherein the second subset of bits precedes the first subset of bits in the output.

3. The system of claim 2, wherein the second subset of bits comprises a first bit of DQ bits, and the first subset of bits comprises the remaining bits of the output.

4. The system of claim 1, wherein the PHY comprises a plurality of input buffer latches each configured to latch input data from a respective DQ pad of the plurality of DQ pads.

5. The system of claim 4, wherein the shift chain of registers comprises a plurality of shift registers configured to:
latch in an output from a respective input buffer latch of the plurality of input buffer latches for the first subset of bits; and
serially shift the first subset of bits out of the shift chain in a serialized manner upon consecutive clock cycles.

6. The system of claim 5, wherein a respective one or more input buffers of the plurality of input buffers corresponding to the second subset of bits does not transmit the second subset of bits to the plurality of shift registers.

7. The system of claim 5, wherein the plurality of shift registers comprises one shift register that does not latch data directly from one of the plurality of input buffers but shifts the first subset of bits in serialization into the output.

8. The system of claim 1, comprising selection circuitry configured to select between the first path and the second path for combining to generate the output.

9. The system of claim 8, comprising a control latch configured to:
generate a selection signal to select the second path for a first one or more bits and to select the first path for subsequent bits; and
transmit the selection signal to the selection circuitry.

10. The system of claim 9, wherein the control latch is configured to:
receive a reset signal;
in response to receiving the reset signal, reset the selection signal to the second path for a first one or more of the bits of the plurality of DQ pads, wherein the first one or more of the bits comprises the second subset of bits;
receive a shift signal indicating that the first subset of bits is to be shifted through the shift chain of registers; and
in response to receiving the shift signal, change the selection signal to the first path.

11. The system of claim 10, wherein an input of the control latch is set to select the first path when the shift signal is received at a clock input of the control latch.

12. The system of claim 1, comprising a delay configured to delay a clock used to capture the first subset of bits captured into the shift chain of registers, wherein the second subset of bits are not impacted by the delayed clock.

13. The system of claim 1, wherein the PHY is configured to use the first and second paths for high-bandwidth memory (HBM) EXTEST instructions.

14. An interface die of a memory device, comprising:
a plurality of data (DQ) pads configured to send and receive data at the interface die as bits, wherein the bits comprise a first subset of bits and a second subset of bits;
a plurality of input buffers configured to capture the bits in parallel from the plurality DQ pads using a clock;
a delay configured to delay the clock; and
serialization circuitry configured to serialize the bits from the parallel capture of bits in the plurality of input buffers and to output a serial output, wherein the serialization circuitry comprises:
a shift chain comprising a plurality of shift chain registers configured to serialize the second subset of bits into the serialized output using the delayed clock; and
a multiplexer configured to:
select the first subset of bits as a beginning of the serialized output from a corresponding input buffer of the plurality of input buffers bypassing the plurality of shift chain registers and independent of the delayed clock; and
select the second subset of bits from the shift chain for the second subset of bits subsequent to the first subset of bits.

15. The interface die of claim 14, wherein the memory device comprises a high-bandwidth memory (HBM), and the bits are captured in the plurality of input buffers as part of an EXTEST instruction.

16. The interface die of claim 14, comprising a control latch configured to:
generate a selection signal to cause the multiplexer to select the first subset of bits for a first one or more bits and to select the second subset of bits for subsequent bits; and
transmit the selection signal to the multiplexer.

17. The interface die of claim 16, wherein the control latch is configured to:
receive a reset signal;
in response to receiving the reset signal, reset the selection signal to the first subset of bits;
receive a shift signal indicating that the second subset of bits is to be shifted through the shift chain; and
in response to receiving the shift signal, change the selection signal to the second subset of bits from the shift chain.

18. A memory device, comprising:
a plurality of data (DQ) pads configured to send and receive data at an interface die of the memory device as bits, wherein the bits comprise a first bit and a second subset of the bits;
a plurality of input buffers configured to capture the bits in parallel from the plurality DQ pads using a clock;
a delay configured to delay the clock; and
serialization circuitry configured to serialize the bits from the parallel capture of bits in the plurality of input buffers and to output a serial output, wherein the serialization circuitry comprises:
a first path comprising a shift chain having a plurality of shift chain registers configured to serialize the second subset of bits into the serialized output using the delayed clock; and
a multiplexer configured to:
select a second path for the serialization of the first bit into the serialized output, wherein the second path comprises transmission from a corresponding input buffer of the plurality of input buffers bypassing the plurality of shift chain registers, wherein the second path is independent of the delayed clock; and
select the second path for the second subset of bits.

19. The memory device of claim 18, comprising a control latch configured to:
generate a selection signal to cause the multiplexer to select the path for the first bit and to select the second path for the second subset of bits subsequent to the first bit; and
transmit the selection signal to the multiplexer.

20. The memory device of claim 19, wherein the control latch is configured to:
receive a reset signal;
in response to receiving the reset signal, reset the selection signal to the first bit;
receive a shift signal indicating that the second subset of bits is to be shifted through the second path; and
in response to receiving the shift signal, change the selection signal to the second path.
